(19) United States
(12) Patent Application Publication
(10) Pub. No.: US 2016/0043050 A1
(43) Pub. Date: Feb. 11, 2016

(54) Metallization stack and chip arrangement

(71) Applicant: Infineon Technologies AG, Neubiberg (DE)

(72) Inventor: Swee Kah LEE, Seri Jati Batu Berendam (MY)

(21) Appl. No.: 14/821,705

(22) Filed: Aug. 8, 2015

(30) Foreign Application Priority Data
Aug. 11, 2014 (DE) 10 2014 111 435.3

(51) Int. Cl. H01L 23/00; B32B 15/01; H01L 23/495

(52) U.S. Cl. CPC H01L 24/14; H01L 24/17; H01L 23/4952; B32B 15/01; B32B 15/018; H01L 2924/01029; H01L 2924/01028; H01L 2924/01079; H01L 2924/01047; H01L 2924/01078; H01L 2924/0132; H01L 2924/0103

(57) ABSTRACT

A metallization stack for a chip arrangement is provided, wherein the metallization stack comprises a first metallic layer; a plating layer comprising an alloy comprising nickel and zinc arranged over the first metallic structure; and a second metallic layer arranged over the plating layer.

### TECHNICAL FIELD

Various embodiments relate to a metallization stack for a chip arrangement or packaged chip, in particular for non-reflow flip chip connecting, and a chip arrangement comprising a metallization stack.

### BACKGROUND

In the prior art a plurality of packaged chips or electronic modules are known comprising metallization stacks used for electrically connecting different elements or components of the packaged chip or electronic module. For example, such metallization stacks are used to electrically connect chips or dies to a leadframe or carrier. Some examples of such metallization stacks and the usage of the same are shown in FIG. 5A to FIG. 5D.

In particular, FIG. 5A shows a metallization stack 500 comprising a copper layer 501 and having arranged thereon a silver layer 502 acting as an adhesion layer for contacting a chip or die, e.g. via bonding. The metallization stack 500 may be used for contacting a thin small non-leaded package (TSNP) as shown in FIG. 5B. In particular, FIG. 5B shows portions of a leadframe 510 onto which metallization stacks 500 are arranged onto which, in turn, a chip 511 is connected to, e.g. by bonding or soldering.

Furthermore, FIG. 5C shows an alternative metallization stack 520 comprising a nickel layer 521, an intermediate gold layer 522 and a silver layer 523 arranged thereon. The metallization stack 520 may be used for contacting a thin small leadless package (TSLP) as shown in FIG. 5D. In particular, FIG. 5D shows portions of a leadframe 530 onto which metallization stacks 520 are arranged, onto which, in turn, a chip 531 is connected to, e.g. by bonding or soldering.

One issue when using packaged chips comprising metallization stacks is that these metallization stacks are subjected to stress, e.g. thermal stress or mechanical stress, during chip or die bond and the subsequent test and/or operation, which may result in the forming of voids in the metallization stack leading to the danger of delamination of layers and/or component. Such voids or delamination may cause cracks or breaks of electrical contacts or connectors in the packaged chip or electronic module such a packaged chip may be used and thus may cause failures of the packaged chip or the whole electronic module.

### SUMMARY

Various embodiments provide a metallization stack for a chip arrangement, wherein the metallization stack comprises a first metallic layer; a plating layer comprising an alloy comprising nickel and zinc arranged over the first metallic structure; and a second metallic layer arranged over the plating layer.

Furthermore, various embodiments provide a leadframe comprising a solder joint matrix, wherein the solder joint matrix comprises a plating layer of an alloy comprising zinc and nickel.

Moreover, various embodiments provide a chip arrangement comprising a metallization stack; and an electronic chip electrically connected to the metallization stack.

### BRIEF DESCRIPTION OF THE DRAWINGS

In the drawings, like reference characters generally refer to the same parts throughout the different views. The drawings are not necessarily to scale. Instead emphasis is generally being placed upon illustrating the principles of the invention. In the following description, various embodiments are described with reference to the following drawings, in which:

FIGS. 1A to 1F schematically depict chip arrangements and corresponding metallization stacks according to exemplary embodiments;

FIGS. 2A to 2F depict test specimens of metallization stacks comprising a layer of zinc/nickel alloy according to exemplary embodiments;

FIGS. 3A to 3F depict test specimens of metallization stacks without zinc in the stack;

FIGS. 4A and 4B depict detail views of a metallization stack without and with zinc;

FIGS. 5A to 5D schematically depict chip arrangements and corresponding metallization stacks; and

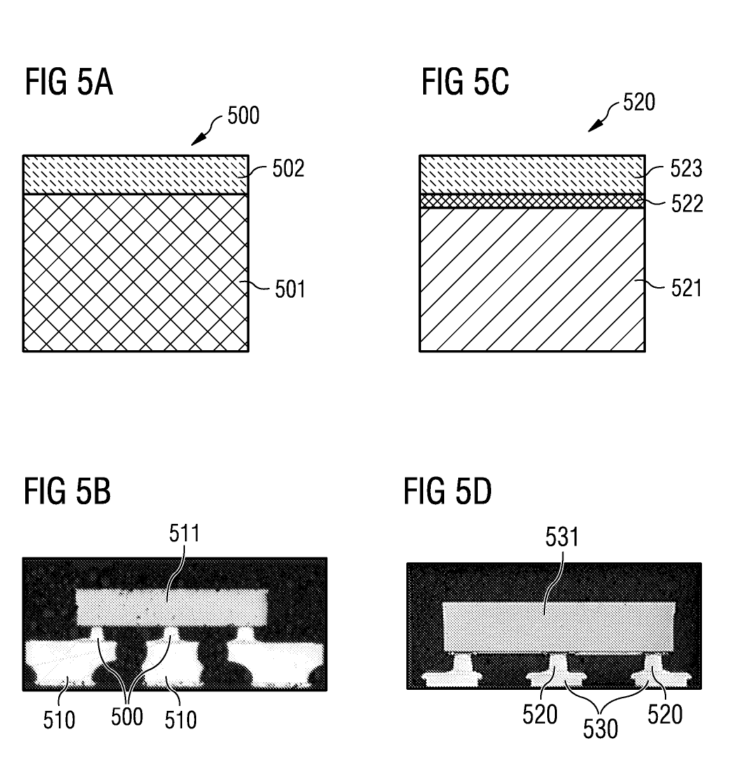

FIG. 6A to 6C schematically depict a further use of a metallization stack according to an exemplary embodiment.

### DETAILED DESCRIPTION

In the following further exemplary embodiments of a metallization stack for a chip arrangement and/or packaged chip and/or an electronic module, of a leadframe, of a chip arrangement, a method of manufacturing a metallization stack will be explained. It should be noted that the description of specific features described in the context of one specific exemplary embodiment may be combined with others exemplary embodiments as well.

The word “exemplary” is used herein to mean “serving as an example, instance, or illustration”. Any embodiment or design described herein as “exemplary” is not necessarily to be construed as preferred or advantageous over other embodiments or designs.

Various exemplary embodiments provide a metallization stack comprising a multi-layer structure, one of which is a metallic layer and another one arranged over the metallic layer is a plating layer wherein the plating layer comprises an alloy of nickel and zinc.

The term “metallization stack” may particularly denote a multi-layer structure comprising a plurality of electrically conductive layer (typically but not necessarily metallic) which may be used to contact or electrically connect different components (e.g. leadframe and chip or die) or portions in an electric/electronic circuitry.

Furthermore, various embodiments provide a method of manufacturing a metallization stack, wherein the method comprises providing a first metallic layer; plating a plating layer over the first metallic layer, wherein the plating layer comprises an alloy of nickel and zinc; and arranging a second metallic layer over the plating layer.

In particular, the plating layer may be directly plated onto the first metallic layer and/or the second metallic layer may be directly arranged or deposited onto the plating layer. Alternatively, additional layers, e.g. intermediate layer(s) and/or adhesion layer(s) may be arranged, plated or formed between the first metallic layer, the plating layer and/or the second metallic layer.

In particular, the first metallic layer may comprise or may substantially consist of copper, nickel or other materials typically used for leadframes or carriers in the field of semiconductor packages. For example, the first metallic layer may be a leadframe, a carrier or a layer arranged on a leadframe or carrier. In particular, the second metallic layer may form a metallization layer used for contacting a solder bump, a copper pillar, an adhesion layer, a contact pad or contact layer, e.g. of a semiconductor chip or die, or the like.

In particular, the electronic chip or integrated chip may be directly connected to the metallization stack, e.g. to the second metallic layer. For example, the electronic chip may be bonded or soldered to the metallization stack. A suitable method for connecting may be a non-reflow flip chip process or connecting. In particular, the metallization stack may be adapted to be connected or contacted during a non-reflow flip chip process. For example, the chip arrangement may form (together or without a mold compound) a semiconductor package or even an electronic module. It should be noted that the chip arrangement may of course comprise a plurality of metallization stacks and/or electronic chips. For example, the number of metallization stacks may correspond to the number of electronic chips or dies.

The use of zinc in the metallization stack may provide for an improvement in joint robustness (e.g. with respect to shear, stress or the like), in particular of solder joints, when used as an inner package structure, e.g. for connecting a leadframe with a die, in a packaged chip or electronic module. In particular, it may be possible to reduce the probability and/or extend to which voids are formed during staging bonding procedures and/or the operation of the packaged chip or electronic module. Furthermore, solder joint produced by using the metallization stack, e.g. during a later flip chip bonding, may be improved with respect to ductility and/or thermal stability. In addition the zinc may also enhance adhesion of the second metallic layer to a mold compound used later on to encapsulate a connected die or chip.

In particular, the introduction of zinc into one or a plurality of metallization stacks which may form a kind of solder join matrix, may (during a later soldering process) reduce the speed or amount tin is consumed in the soldering process which consumption would otherwise leading to the forming of voids in the metallization stack. Such voids are typically generated or created during chip bonding or staging. For example, Ag₃Sn or Cu₃Sn intermetallic compound growth may be reduced or slowed down, when including zinc into the metallization stack or silver and/or copper may be stabilized by the zinc. It may also be possible to increase the staging time in case that zinc is used in the metallization stack without increasing the number or size of the generated voids. Thus, the robustness may be increased due to the use of zinc even decreasing the probability of solder cracks after heat staging to temperatures up to 200° C. or even higher.

In the following exemplary embodiments of the metallization stack are described. However, the features and elements described with respect to these embodiments can be combined with exemplary embodiments of the leadframe, of the chip arrangement, the method of manufacturing a metallization stack and an electronic module comprising a metallization stack

According to an exemplary embodiment the metallization stack further comprises an intermediate layer comprising palladium arranged on the plating layer.

In particular, the intermediate layer may comprise palladium or may consist substantially or completely of palladium. In the context of this application the term “substantially consist” may mean that the respective layer comprises only, except of unintentional impurities, of the respective material, e.g. palladium. That is no additional material or chemical element is added intentional into the respective layer. The provision of an additional intermediate layer comprising palladium or a palladium layer may improve with respect to shear stability of the metallization stack or even of a total semiconductor package the metallization stack is used in, in particular in case the second metallic layer arranged above or directly on the plating layer may be a silver layer or at least comprising silver. In addition, palladium may improve the wettability with respect to solder in a soldering process. Furthermore, the intermediate layer may act as an anti-immersion layer so that it may be enabled or facilitated a plating of the second metallic layer. For example, no additional layer or material may be necessary in case a silver layer forms the second metal layer to be arranged or plated on the plating structure, e.g. comprising first metal layer, plating layer, palladium layer at that time.

According to an exemplary embodiment of the metallization stack the plating layer is plated on the first metal layer.

In particular, the plating layer may be directly plated on the first metal layer, i.e. no additional layer is formed between the first metal layer before plating the plating layer onto the first metal layer.

For example, the intermediate layer may be arranged directly on the plating layer.

According to an exemplary embodiment of the metallization stack the alloy of the plating layer comprises between 85% and 95% zinc and between 5% and 15% nickel.

According to an exemplary embodiment of the metallization stack a thickness of the plating layer is between 0.1 micrometer and 0.5 micrometer.

In particular, a thickness of the first metal layer may be between 15 micrometer and 30 micrometer, while a thickness of the second metal layer may be between 1 micrometer and 4 micrometer. Suitable thicknesses of an optional palladium layer may be in the range of 0.01 micrometer and 0.15 micrometer.

According to an exemplary embodiment the metallization stack further comprises an interposing layer arranged between the first metallic layer and the plating layer.

In particular, the interposing layer may function as a matching layer enabling or enhancing an adhesion, reducing stress or strain resistance, decreasing shear, or alike of the metallization stack by matching or mediating between some characteristics of the first metal layer and the plating layer.

According to an exemplary embodiment of the metallization stack the first metallic layer comprises copper and the interposing layer comprises nickel.

According to an exemplary embodiment of the metallization stack the second metallic layer is an adhesion layer comprising at least one material out of the group consisting of: gold; gold alloys; platinum; gold/platinum alloys; copper; and silver.

According to an exemplary embodiment the metallization stack further comprises a bonding wire bonded to the metallization stack.

In particular, the bonding wire may be bonded to the second metallic layer.

According to an exemplary embodiment of the metallization stack the first metallic layer is a metal pillar.

In particular, the metal pillar may be an aluminum pillar or copper pillar being part of a bump often used in the field of flip chip interconnecting. It should be noted that as well in the case of a copper pillar an additional palladium layer may optionally formed between the plating layer (nickel/zinc alloy) and the second metallic layer. In addition optional intermediate or adhesive layers may be arranged as well. For example, a nickel layer may be arranged between a copper pillar and the plating layer.

In the following exemplary embodiments of the leadframe are described. However, the features and elements described with respect to these embodiments can be combined with exemplary embodiments of the metallization stack, of the chip arrangement, the method of manufacturing a metallization stack and an electronic module comprising a metallization stack.

According to an exemplary embodiment of the leadframe the solder joint matrix comprises a metallic layer arranged over the plating layer.

In particular, the metallic layer may comprise silver or may substantially consist of silver.

According to an exemplary embodiment of the leadframe the solder joint matrix is formed by a selective patterning process.

In particular, the introduction of zinc or an alloy comprising zinc and nickel in a metallization stack or solder joint matrix may increase solder joint robustness (in particular for flip chip binding) in term of ductility and thermal stability. Furthermore, when using an additional optional layer of palladium improvement of die shear may be done and the palladium layer may add as anti-immersion layer, e.g. in the case of using a silver layer as an adhesion layer, for example, so that no additional intermediate layer may be necessary.

In the following exemplary embodiments of the chip arrangement are described. However, the features and elements described with respect to these embodiments can be combined with exemplary embodiments of the metallization stack, of the leadframe, the method of manufacturing a metallization stack and an electronic module comprising a metallization stack.

According to an exemplary embodiment of the chip arrangement the electronic chip is a chip package and is one selected out of the group consisting of: thin small non-leaded packages; thin small leadless packages; and extreme thin small non-leaded packages.

According to an exemplary embodiment of the chip arrangement the electronic chip is bonded onto the metallization stack.

According to an exemplary embodiment of the chip arrangement in the electronic chip is electrically connected to the metallization stack via wire bonding.

According to an exemplary embodiment of the chip arrangement the electronic chip is connected to the metallization stack by a non-reflow flip chip process.

In the following specific embodiments of the metallization stack will be described in more detail with respect to the figures.

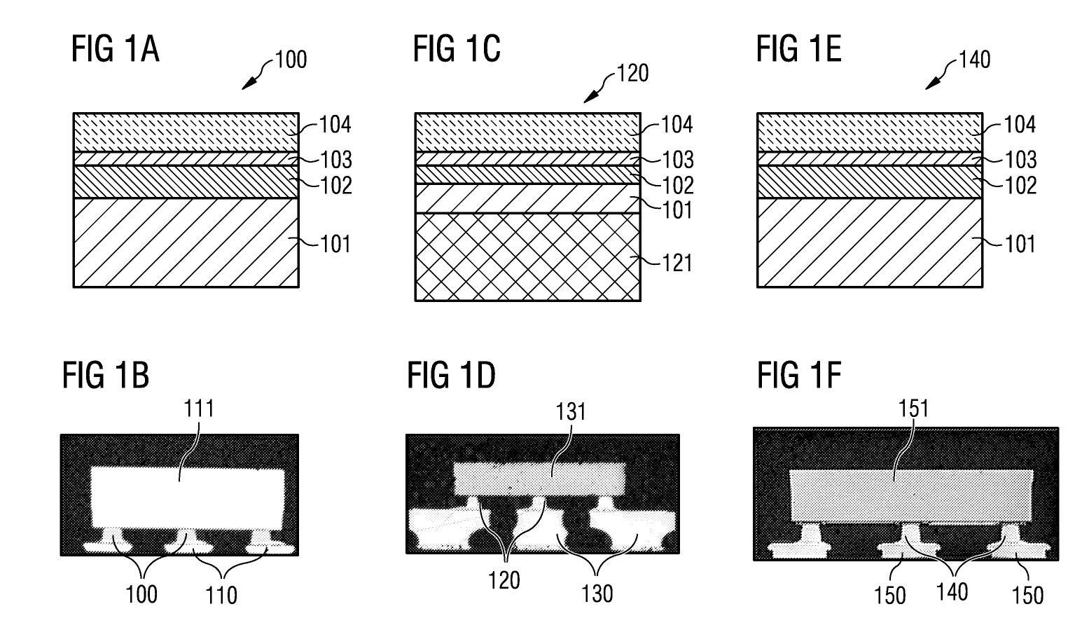

FIGS. 1A to 1F schematically depict chip arrangements and corresponding metallization stacks according to exemplary embodiments. In particular, FIG. 1A shows a metallization stack 100 comprising a nickel layer 101, a plating layer 102 directly plated on top of the nickel layer 101 and comprising an alloy of nickel and zinc. Furthermore, the metallization stack 100 comprises a palladium layer 103 arranged on top of the plating layer 102 and functioning as a strengthening and/or immersion protection layer with respect to a silver layer 104 arranged on top of the palladium layer 103, wherein the silver layer may act or function as an adhesion layer.

The described layers of the metallization stack 100 may have the following thicknesses. For example, the nickel layer 101 may have a thickness between 5 micrometer and 50 micrometer (in particular between 15 micrometer and 30 micrometer), the plating layer 102 may have a thickness between 0.05 micrometer and 1 micrometer (in particular, between 0.1 micrometer and 0.5 micrometer), the palladium layer 103 may have a thickness between 5 nanometer and 0.3 micrometer (in particular, between 0.01 micrometer and 0.15 micrometer), while the silver layer 104 may have a thickness between 0.5 micrometer and 10 micrometer (in particular, between 1 micrometer and 4 micrometer).

The metallization stack 100 may be used for contacting an extreme thin small leadless package (e-TSLP) as shown in FIG. 1B. In particular, FIG. 1B shows portions of a leadframe 110 onto which metallization stacks 100 are arranged, onto which, in turn, a chip 111 is connected to, e.g. by bonding or soldering.

In particular, FIG. 1C shows a metallization stack 120 which is similar the one shown on FIG. 1A however comprising a further copper layer 121.

The layers of the metallization stack 120 may have the following thicknesses. For example, the copper layer or base 121 may have a thickness about between 50 micrometer and 250 micrometer (e.g. 125 micrometer), the nickel layer may have a thickness between 0.25 micrometer and 5 micrometer (in particular, between 0.5 micrometer and 2.0 micrometer), the plating layer may have a thickness between 0.05 micrometer and 1 micrometer (in particular, between 0.1 micrometer and 0.5 micrometer), the palladium layer may have a thickness between 0.05 micrometer and 0.3 micrometer (in particular, between 0.01 micrometer and 0.15 micrometer), while the silver layer may have a thickness between 0.05 micrometer and 10 micrometer (in particular, between 1 micrometer and 4 micrometer).

The metallization stack 120 may be used for contacting a thin small non-leaded package (TSNP) as shown in FIG. 1D. In particular, FIG. 1D shows portions of a leadframe 130 onto which metallization stacks 120 are arranged, onto which, in turn, a chip 131 is connected to, e.g. by bonding or soldering.

In particular, FIG. 1E shows a metallization stack 140 which is like the one shown on FIG. 1A however it is used for contacting a thin small leadless package (TSLP) as shown in FIG. 1F. In particular, FIG. 1F shows portions of a leadframe 150 onto which metallization stacks 140 are arranged, onto which, in turn, a chip 151 is connected to, e.g. by bonding or soldering.

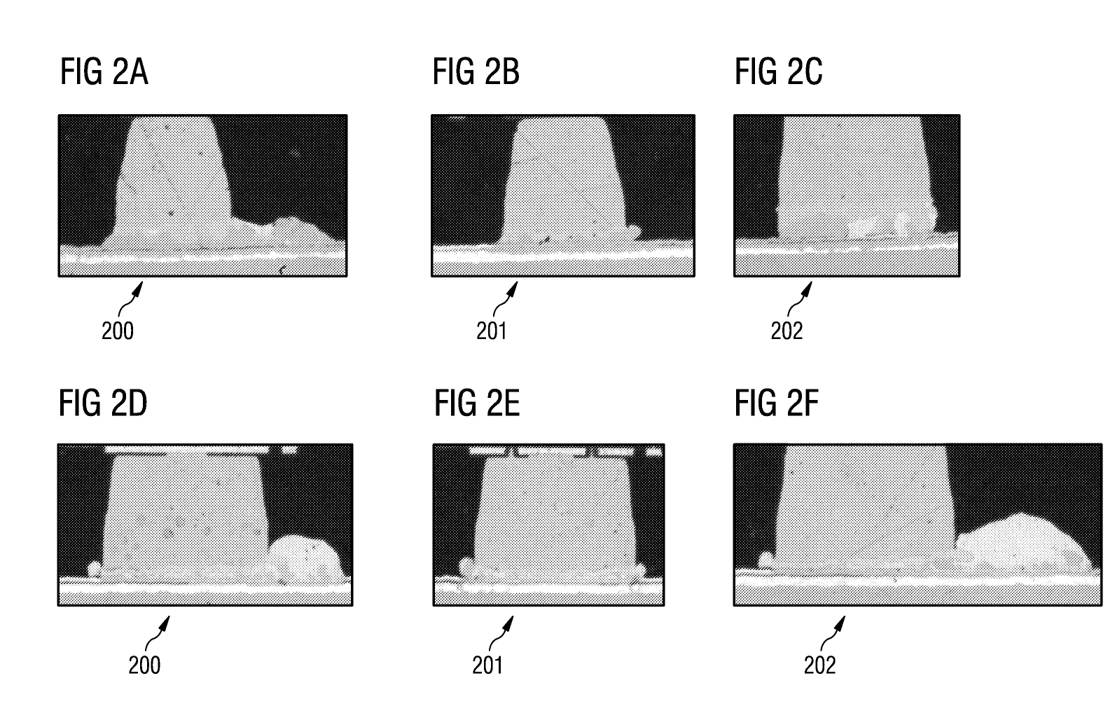

FIGS. 2A to 2F depict test specimens of metallization stacks comprising a zinc/nickel alloy according to exemplary embodiments. In particular, FIG. 2A to FIG. 2C show metallization stacks 200, 201 and 202 according to an exemplary embodiment, in particular comprising a zinc/nickel layer but no optional palladium layer, before a staging process or step. FIG. 2D to 2F show the corresponding metallization stacks 200, 201 and 202, respectively, after a staging process of 2 hours at 250° C. As can be seen in the FIG. 2D to FIG. 2F no voids or solder cracks are formed after the staging.

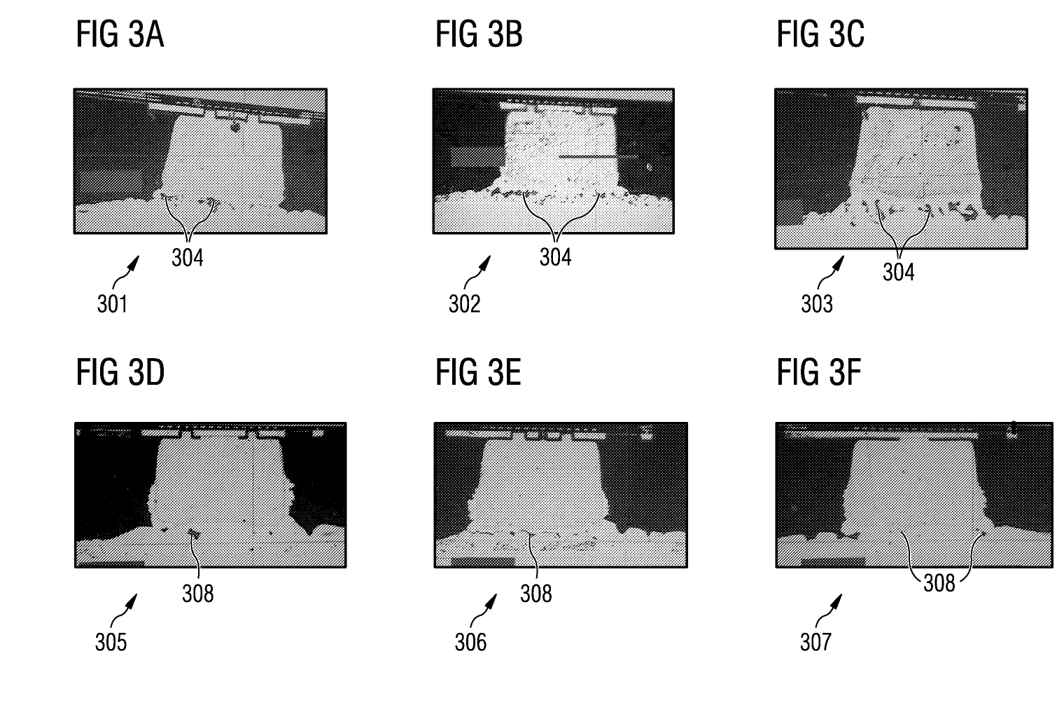

As a contrast to the metallization stacks of FIG. 2A to FIG. 2F, FIGS. 3A to 3F depict test specimen of metallization stacks without zinc. In particular, FIG. 3A, FIG. 3B and FIG. 3C show metallization stacks 301, 302, and 303 used with an e-TSLP and clearly showing voids 304. The same holds true for the FIG. 3D to FIG. 3F showing metallization stacks 305, 306, and 307, respectively used with a TSLP and as well clearly showing voids 308.

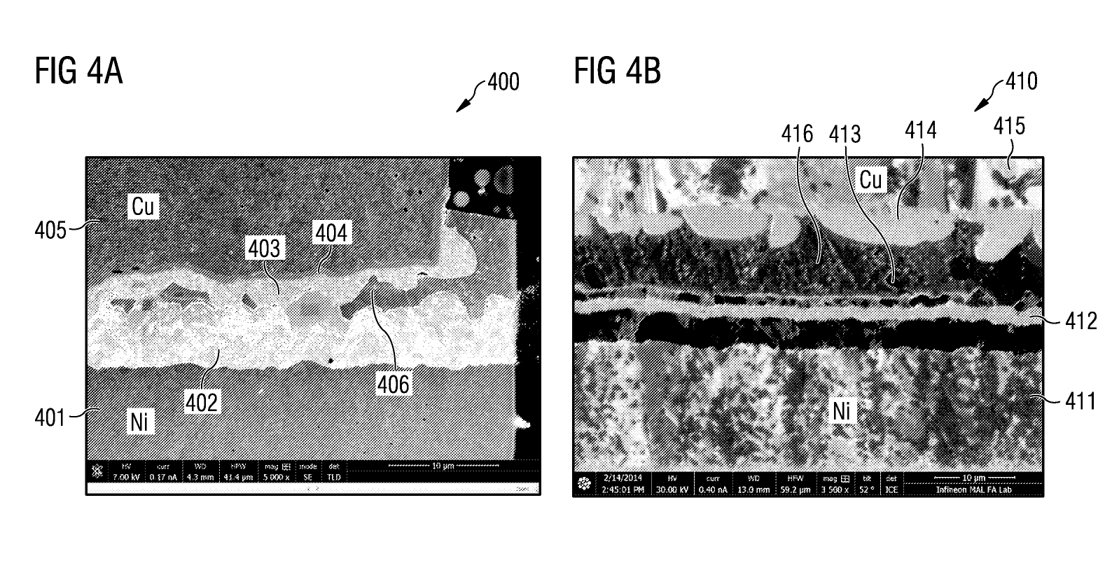

FIGS. 4A and 4B depict detail views of a metallization stack without zinc 400 and a metallization stack with zinc 410 both used for TSLP chips after a staging process at 250° C. for 2 hours. In particular, one can see that the metallization stack 400 comprises a nickel base 401 onto which a silver/tin layer 402 having a granular structure was formed during the staging process while a copper tin (Cu₆Sn₅) layer 403 and a further copper tin (Cu₃Sn) layer 404 was formed from a copper pillar 405. Furthermore, one can see a ductile tin rich area 406 which will be consumed and thus causing voids.

On contrary, metallization stack 410 comprise a nickel base 411 onto which a nickel zinc alloy layer 412 is formed. In addition a silver tin (Ag₃Sn) layer 413 formed during the staging process can be seen as well as a copper tin (Cu₆Sn₅) layer 414 formed from a copper pillar 415. As can be seen in FIG. 4B the silver tin layer 413 is less granular and finer as in the stack of FIG. 4A having no nickel/zinc alloy. Also a tin rich area 416 can be seen in FIG. 4B which will not be consumed afterwards.

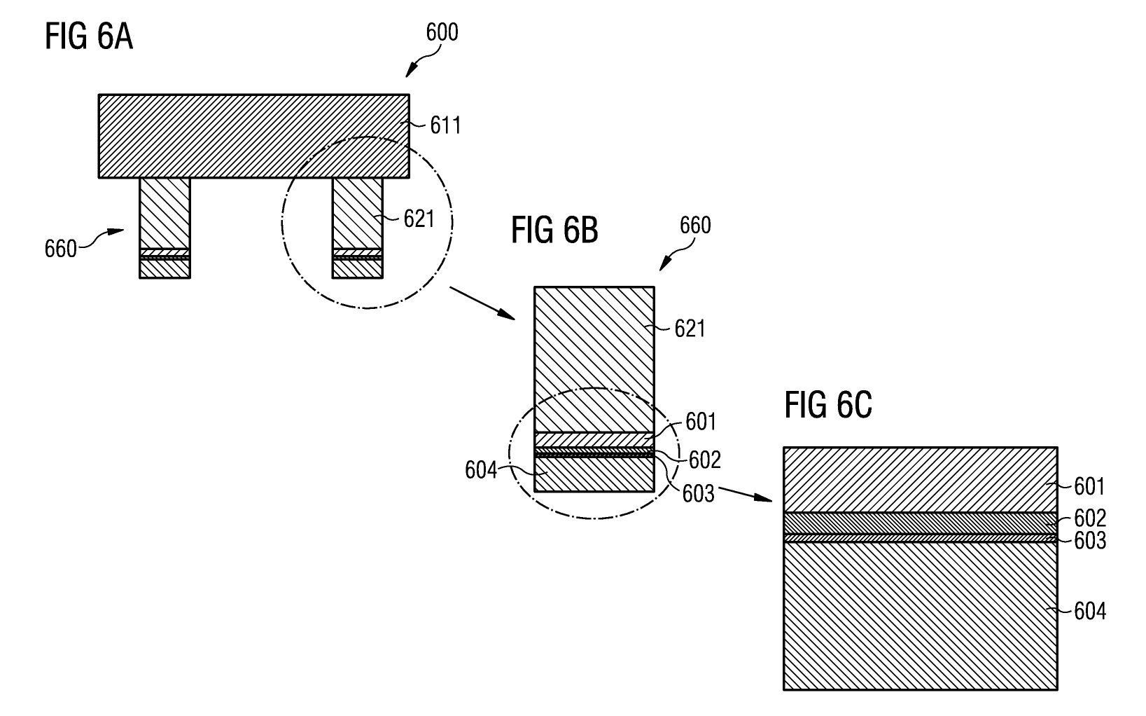

FIG. 6A to 6C schematically depict a further use of a metallization stack according to an exemplary embodiment. In particular, FIG. 6A schematically shows a chip arrangement 600 comprising a chip or die 611 having arranged thereon a metallization stack or bump 660 comprising a metal pillar, e.g. of copper, 621 and further comprising several additional layers which can be more clearly seen in the detail views of FIG. 6B and FIG. 6C.

FIG. 6B shows the copper layer 621, and the further layers arranged thereon, in particular, a nickel layer 601, a plating layer 602 comprising or consisting of a nickel/zinc alloy, a palladium layer 603 and a further optional metallic layer 604, which may comprise silver and/or a silver tin alloy or another suitable metal. In general the thicknesses of the different layers may be the same as described above in the context of FIG. 1.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A metallization stack for a chip arrangement, the metallization stack comprising:
a first metallic layer;
a plating layer comprising an alloy comprising nickel and zinc arranged over the first metallic structure; and
a second metallic layer arranged over the plating layer.

2. The metallization stack according to claim 1, further comprising an intermediate layer comprising palladium arranged on the plating layer.

3. The metallization stack according to claim 1, wherein the plating layer is plated on the first metal layer.

4. The metallization stack according to claim 1, wherein the alloy of the plating layer comprises between 85% and 95% zinc and between 5% and 15% nickel.

5. The metallization stack according to claim 1, wherein a thickness of the plating layer is between 0.1 micrometer and 0.5 micrometer.

6. The metallization stack according to claim 1, further comprising an interposing layer arranged between the first metallic layer and the plating layer.

7. The metallization stack according to claim 6, wherein the first metallic layer comprises copper and the interposing layer comprises nickel.

8. The metallization stack according to claim 1, wherein the second metallic layer is an adhesion layer comprising at least one material out of the group consisting of:
gold;
gold alloys;
platinum;
gold/platinum alloys;
copper; and
silver.

9. The metallization stack according to claim 1, further comprising a bonding wire bonded to the metallization stack.

10. The metallization stack according to claim 1, wherein the first metallic layer is a metal pillar.

11. A leadframe comprising a solder joint matrix wherein the solder joint matrix comprises a plating layer of an alloy comprising zinc and nickel.

12. The leadframe according to claim 11, wherein the solder joint matrix comprises a metallic layer arranged over the plating layer.

13. The leadframe according to claim 11, wherein the solder joint matrix is formed by a selective patterning process.

14. A chip arrangement comprising:
a metallization stack according to claim 1; and
an electronic chip electrically connected to the metallization stack.

15. The chip arrangement according to claim 14, wherein the electronic chip is a chip package and is one selected out of the group consisting of:
thin small non-leaded packages;
thin small leadless packages; and
extreme thin small non-leaded packages.

16. The chip arrangement according to claim 14, wherein the electronic chip is bonded onto the metallization stack.

17. The chip arrangement according to claim 14, wherein the electronic chip is electrically connected to the metallization stack via wire bonding.

18. The chip arrangement according to claim 14, wherein the electronic chip is connected to the metallization stack by a non-reflow flip chip process.
